(19) United States
(12) Patent Application Publication
(10) Pub. No.: US 2021/0242510 A1
(43) Pub. Date: Aug. 5, 2021

(54) DYNAMIC LEARNING OF BATTERY CAPACITY ESTIMATION FOR ELECTRIC VEHICLE USING VALIDITY CHECK

(71) Applicant: BORDRIN NEW ENERGY VEHICLE CORPORATION, INC., ROYAL OAK, MI (US)

(72) Inventors: YONGHUA LI, ANN ARBOR, MI (US); FOAD SAMADI, WINDSOR (CA)

(21) Appl. No.: 16/776,899

(22) Filed: Jan. 30, 2020

(51) Int. Cl. H01M 10/48; G01R 31/36; G01R 31/382; H01M 2/10

(52) U.S. Cl. CPC H01M 10/482; G01R 31/3648; G01R 31/382; H01M 2220/20; H01M 10/486; H01M 2/1083; H01M 2/1077

(57) ABSTRACT

A battery management system for an electric vehicle is provided. The battery management system may include a battery pack and a battery controller. The battery controller may acquire a first reading of the battery pack in response to first criteria being met, acquire a second reading of the battery pack in response to second criteria being met, and determine an estimated capacity of the battery pack. The battery controller may further validate the estimated capacity in response to third criteria being met. In one example, the capacity of cells is updated in a closed loop manner where both the new learned values and old valid value are engaged. The different learned values of capacity values are adaptively averaged based on the battery conditions such as temperature, accuracy of learned values, time since last update and depth of aging. The proposed methodology updates capacity in a periodic manner where different operation conditions are accommodated to facilitate capacity estimation. It also adopts a conservative method on how to learn new values, and how to merge them with old values so to ensure validity of capacity values.

### BACKGROUND

### 1. Field of the Disclosure

The present disclosure generally relates to battery capacity estimation for an electric vehicle.

### 2. Description of Related Art

Estimating capacity of a battery is important in managing performance of an electric vehicle. However, estimating battery capacity has many challenges and existing state of the art methods can be difficult to keep battery capacity learning updated on a regular basis. As such an improved system and method is needed for battery capacity estimation for an electric vehicle.

### SUMMARY

A battery management system (BMS) for an electric vehicle is provided. The battery management system may include a battery pack and a battery controller. The battery controller may acquire a first reading of battery terminal voltage, battery temperature, and battery current throughput of the battery cell or pack in response to first criteria being met, acquire a second reading of battery terminal voltage, battery temperature, and battery current throughput of the battery cell or pack in response to second criteria being met, and determine an estimated capacity of the battery cell or pack. The battery controller may further validate the estimated capacity in response to third criteria being met.

The battery controller may determine the estimated capacity based on State of Charge (SoC) of battery at two different time instants and an accumulated ampere-hour between the time instants. The estimated capacity of each battery cell may be determined periodically. The estimated capacity of each battery cell may involve two different learned values of capacity and one old value of capacity. The state of charge values may be acquired based on Open-Circuit Voltage (OCV) of the battery cell or pack in equilibrium state. The battery controller may determine if the battery capacity needs to be updated based on the time passed since last update of capacity.

In other aspects of the disclosure, the battery controller may determine the temperature of the battery at the time of the SoC read. The battery controller may determine if the battery has reached to an equilibrium state. The battery controller may determine based on temperature and battery rest time, to read a first value of SoC if a capacity update has to be performed based on time since last update. The battery controller may determine to read a second value of SoC. The battery controller may determine the difference ΔSoC between the second value of SoC, and the first value of SoC, and determine the battery rest time. The battery controller may analyze ΔSoC and battery rest time, and determine a capacity learning procedure shall be initiated, or reset the procedure, or wait and record Ah, or replace the first value of SoC with the second value of SoC and reset Ah reading.

Also, the battery controller may determine the learned capacity using ΔSoC and Ah recorded capacity between first and second value of SoC. The battery controller may determine whether a validation of learned capacity is required. The battery controller may determine based on temperature and battery rest time, to read a third value of SoC. The battery controller may determine the difference ΔSoC between the third value of SoC, and the second value of SoC, and calculates the battery rest time. The battery controller may analyze ΔSoC and battery rest time, and determines a capacity learning procedure shall be initiated, or reset the procedure, or wait and record Ah, or replace the second value of SoC with the third value of SoC and reset Ah. The battery controller may determine a second learned capacity using ΔSoC and Ah recorded capacity between the second value of SoC and the third value of SoC.

The battery controller may determine a validation index with respect to nominal capacity of battery based on the first learned capacity and second learned capacity. The battery controller may determine based on the validation index to update capacity or discard new learning values. The battery controller may analyze the validation index to determine an impact of new learned values in an overall capacity update. The battery controller is configured to perform an adaptive (eg., weighted) averaging between the first and second learned capacity values to identify a new learned capacity of battery cell or pack. The battery controller may compare the new learned capacity with the last valid capacity of the battery cell or pack, analyzes a time passed since a last valid value to identify a depth of aging of the battery cell or pack. The battery controller may employ an analysis of the depth of aging to tune an averaging algorithm with the new learned value of capacity and an old valid value. The battery controller may update the estimated capacity based on the new learned value, the old valid value, and a tuning mechanism.

Further objects, features, and advantages of this invention will become readily apparent to persons skilled in the art after a review of the following description, with reference to the drawings and claims that are appended to and form a part of this specification.

### BRIEF DESCRIPTION OF THE DRAWINGS

FIG. 1 is a block diagram of a battery management system.

FIG. 2 is a schematic view of an RC equivalent circuit model diagram.

FIG. 3 is a flowchart illustrating a method for capacity estimation.

### DETAILED DESCRIPTION

State of Health (SoH) of the battery can be an important parameter of concern in battery monitoring. It can be an important indicator that may be required by end-customers. SoH is often defined in terms of the capacity of the battery with respect to fresh cell capacity, e.g., how much of electrical charge the battery can store before it is over charged. In this regard, accurate estimation of battery capacity can be the key to accurate SoH monitoring. One method is to measure battery capacity using a coulomb counting algorithm where SoC is measured at two instances of battery use, integral of current versus time is calculated between these two data points, and capacity is estimated as Q_{learned}=∫ηI·dt/ΔSoC. The new estimated value may be filtered using a weighted averaging methodology that combines the new value with old value.

There are a couple of drawbacks in the above described method that this proposal can address and improve. First, the estimation of battery cell or pack capacity Q can be performed in an open-loop structure where no validation on the accuracy of estimated capacity Q is conducted. Due to the averaging mechanism between old value and current estimated value, a corrupted capacity estimated value could corrupt the capacity estimation for the entire life of the battery usage. There are a number of different factors that can impact the accuracy of battery capacity estimation such as: accuracy of calculated SoC values, charging efficiency values, temperature variation, battery conditions under which the estimation is performed, battery usage profile such as current profile, the averaging that may be performed between old and new learned values, or other parameters. However, for existing methods, there is no compensation mechanism incorporated for the mentioned uncertainty factors. Moreover, in the weighted averaging methodology, only the time instances between current estimation time and the old estimation time is considered and no other conditions regarding the accuracy of estimated battery cell or pack capacity value Q_{learned} and Q_{old} is considered. Also, the acquired SoC values may be restricted to be measured at two consecutive events of Keyon to Keyoff which may not be readily available, thus impede capacity estimation, and also influence its accuracy depending the specific vehicle usage patterns.

This disclosure provides improvement of battery capacity estimation methodologies to address the aforementioned drawbacks. The proposed method may provide a validation of the estimated capacity by using a second estimation of the current capacity. Consistency between estimated capacity values would increase the confidence in estimated values and thus old estimated values can be corrected more effectively, and in a timely manner.

In another aspect of this disclosure, a more dynamic and sophisticated mechanism is provided for averaging between new learned values and old values of battery capacity. This is to address the fact that battery capacity estimation is done in a periodic manner and aging of that battery has gone through in each period could be different depending on the usage pattern of the battery, weather conditions, and road conditions, among others. A new update scheme for capacity value that reflects the estimation accuracy of new learned capacity value and the difference between old value and new learned value is proposed in this disclosure.

Also, provided in this disclosure is a new scheme on how to collect and merge required data to perform capacity estimation to facilitate the capacity estimation under different driving patterns.

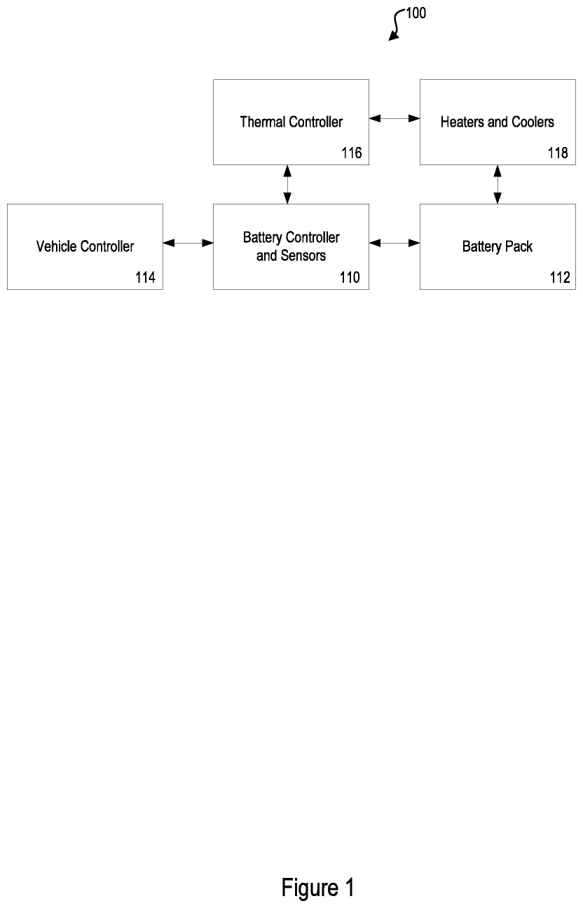

FIG. 1 is a block diagram illustrating a battery management system (BMS). The system may include a battery controller 110 and a battery pack 112. The battery controller 110 may receive inputs from sensors that monitor battery characteristics including temperature, voltage, current, as well as other characteristics described throughout. Additionally, the battery controller 110 may connect or disconnect the battery from various components using various switches. The battery pack may be configured for an electric vehicle and may be a Lithium-ion battery pack or may use other battery technologies. The battery controller 110 may be in communication with a vehicle controller 114 to receive vehicle information including speed, acceleration, location, distance travelled, or other parameters related to the vehicle performance from the vehicle controller 114. Additionally, the vehicle controller 114 or a network may provide the battery controller 110 access to other vehicle systems such as a global positioning system (GPS) or other subsystems to receive information that can be used to control or monitor the battery pack 112.

The battery controller 110 may also be in communication with a thermal controller 116. The thermal controller 116 may heat or cool the battery pack 110 using a heater or cooler 118. The heating or cooling may be based on various measured or calculated variables of the battery pack 110 and/or additional information related to the vehicle or vehicle subsystems.

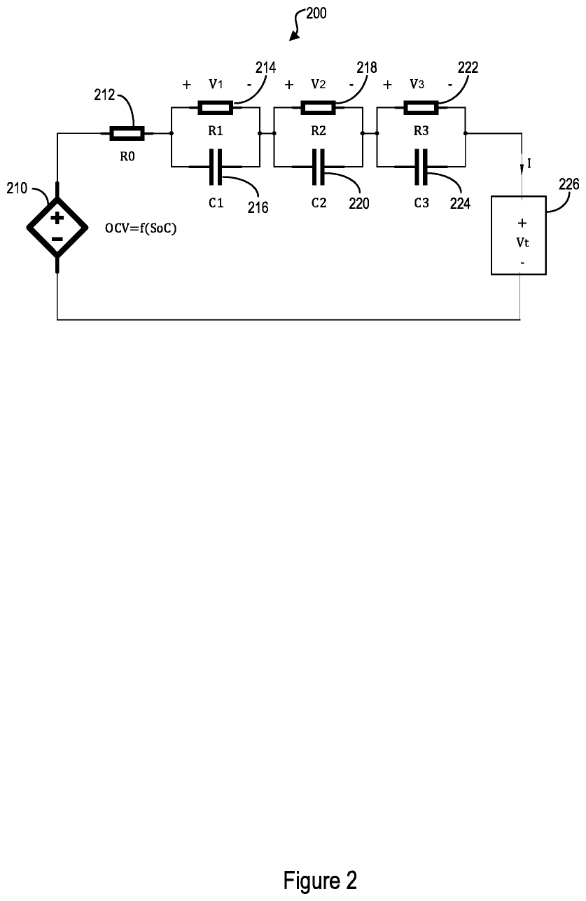

FIG. 2 is a schematic view of an RC equivalent circuit model diagram used to represent the dynamic behavior of the battery. The battery is represented by a third-order model circuit. All model parameters R0, R1, C1, R2, C2, R3, and C3 are known battery parameters as functions of the battery temperature (and at times, battery state of charge). The battery SOC is a nonlinear monotonic increasing function of an open-circuit voltage when the battery is in equilibrium state for each battery temperature. Such a function is represented by the characteristic OCV-SOC curves for the battery at various temperatures.

A power source 210 (e.g. battery) is provided that represents the OCV=f(SoC). The circuit 200 includes a resistance R0 represented by resistor 212. The circuit 200 includes a first load including a resistance R1 and a capacitance C1 (e.g. in parallel) that causes a voltage drop of V1 which is represented by resistor 214 and capacitor 216 (e.g. connected in parallel). The first load may be in series (e.g. or parallel not shown) with additional loads, such as a second and third load. The second load may include a resistance R2 and a capacitance C2 (e.g. in parallel) that causes a voltage drop of V2 which is represented by resistor 218 and capacitor 220 (e.g. connected in parallel). Meanwhile, the third load may include a resistance R3 and a capacitance C3 (e.g. in parallel) that causes a voltage drop of V3 which is represented by resistor 222 and capacitor 224 (e.g. connected in parallel). The loads may collectively generate a current flow of I and a total voltage drop of Vₜ which may be measured by a measurement device 226 (e.g. which may include an amp meter and/or volt meter).

In one implementation, the battery capacity may be calculated in a periodic manner where at two successive instances of Keyon events, SoC value is calculated and captured, and learned capacity is calculated, for example, as follows. Here I is the battery current as a function of time, η is the charging efficiency of the battery (whereas discharge efficiency is considered to be 1), and SoC2 and SoC1 are the two SoCs mentioned above.

$${Q}_{learned} = \frac{\int η I . dt}{Δ S o C} = \frac{\int η I . dt}{S o {C}_{2} - S o {C}_{1}}$$

In this implementation, a validation stage is added to estimation, and updating scheme of the capacity value is also modified accordingly which provides a dynamic framework for battery capacity update. Also, the necessity of capturing SoC in consecutive driving cycles is modified in a manner that provides more flexibility for the software to perform the estimation in a more frequent manner which would lead to a more accurate estimation of capacity and state of health value. Therefore, the following aspects of the proposed system may include:

To have an accurate estimation of SoC, and hence battery capacity, SoC is estimated from open circuit voltage (OCV) of the battery when battery has sufficiently rested. Also, ΔSoC between two instances used in battery capacity estimation must meet certain limits so to suppress disturbance and error accumulation impact on capacity estimation.

Depending on the driving pattern, there might be many instances that the above conditions are not met properly in two consecutive Keyon events to be able to measure capacity. Prior art methods will simply abandon the overall estimation process if conditions do not meet to give accurate estimation of capacity. However, discarding captured values of Ah=∫ηI·dt, and SoC₁ if those conditions are not met, will just delay the capacity estimation which may not be necessary.

For instance, consider the situation where a first read of SoC is available, the battery was only relaxed for a short period that does not allow the SoC estimation based on battery voltage readings, or it was driven for a short period that did not create enough ΔSoC, in this implementation, the controller can still keep data, update Ah, and try to do the estimation on the next Keyon event, given the conditions are satisfied rather than discarding the data and start all over again.

In one implementation, Table 1 is provided which depending on the values of ΔSoC, and Keyoff time (i.e. battery rest time), a decision is made as what action must be taken. Depending on the conditions, four possible actions might be adopted which are 1). Continue to update Ah; 2). Discard old value of SoC1, replace it with the latest value of SoC, and reset Ah; 3). Capture SoC2 and perform Q calculation; 4). Reset SoC1 and Ah and look for the next Keyon event to capture SoC1 value. Each range of ΔSoC in Table 1 can be determined by the controller, then update strategies can be chosen in response to the determined range. The actual values of each range may be specific to a battery or vehicle model. Further, all or some of the ranges may be utilized for a specific model.

TABLE 1

| | ΔSoC | | | | |
|---|---|---|---|---|---|
| Rest Time | Too Small | Medium | Relatively OK | OK | Big |
| Short | Continue to | Continue to | Continue to | Continue to | Reset |
| | Update Ah | Update Ah | Update Ah | Update Ah | |
| Medium Short | Continue to | Continue to | Continue to | Continue to | Reset |
| | Update Ah | Update Ah | Update Ah | Update Ah | |
| Medium | Discard Old | Continue to | Capture | Capture | Discard Old |
| | Value of | Update Ah | SoC2, | SoC2, | Value of |
| | SoC1, Reread | | Perform Q | Perform Q | SoC1, Reread |
| | SoC1, Reset | | Calculation | Calculation | SoC1, Reset |
| | Ah and Start | | | | Ah and Start |
| | Over | | | | Over |
| Long | Discard Old | Discard Old | Capture | Capture | Discard Old |
| | Value of | Value of | SoC2, | SoC2, | Value of |
| | SoC1, Reread | SoC1, Reread | Perform Q | Perform Q | SoC1, Reread |
| | SoC1, Reset | SoC1, Reset | Calculation | Calculation | SoC1, Reset |
| | Ah and Start | Ah and Start | | | Ah and Start |
| | Over | Over | | | Over |
| Very Long | Discard Old | Discard Old | Discard Old | Discard Old | Discard Old |
| | Value of | Value of | Value of | Value of | Value of |
| | SoC1, Reread | SoC1, Reread | SoC1, Reread | SoC1, Reread | SoC1, Reread |
| | SoC1, Reset | SoC1, Reset | SoC1, Reset | SoC1, Reset | SoC1, Reset |
| | Ah and Start | Ah and Start | Ah and Start | Ah and Start | Ah and Start |
| | Over | Over | Over | Over | Over |

Short is same as Medium Short in Table 1, but depending on the desired conditions, either of them can be modified as well. For example in case deltaSOC is too small, we can reset for short-period (due to large impact of noise for instance), but let medium-short to update Ah.

The capacity estimation may be performed in two stages where the second capacity calculation is used to validate the first calculation. For prior art, capacity could only be calculated in an open loop manner where no validation on the estimated value was performed. Therefore, if estimated capacity is inaccurate or even faulty, it will affect the capacity estimation and no recovery mechanism is provided.

Depending on the validation results, the contribution of the new learned value in the averaging process is determined.

Two capacity values are calculated as follows:

$${Q}_{learned , 1} = \frac{A {h}_{12}}{Δ S o C} = \frac{{\int }_{{t}_{1}}^{{t}_{2}} η Idt}{S o {C}_{2} - S o {C}_{1}}$$

$${Q}_{learned , 2} = \frac{A {h}_{23}}{Δ S o C} = \frac{{\int }_{{t}_{2}}^{{t}_{3}} η Idt}{S o {C}_{3} - S o {C}_{2}}$$

The two learned values are compared for consistency, and a consistency value is calculated as follows. The value Q_{BOL} is the battery cell or pack capacity at begin-of-life (BOL) of the battery

ϑ=∥(Q_{learned,1}−Q_{learned,2})/Q_{BOL}∥

Q_{learned,1} and Q_{learned,2} must be acquired in a relatively close time to each other compared to the periods of capacity estimation. Due to slow dynamics of capacity, and the fact that capacity values are measured relatively close to each other, it is expected that Q_{learned,1} and Q_{learned,2} are close and their difference is much smaller than Q_{BOL}.

Consistency value is checked with pre-defined boundaries, and appropriate decision is taken depending on the consistency level acquired. The decision could include the weight of Q_{learned} in overall capacity estimation, or the decision to discard the values and not performing any update.

The new learned value for capacity is calculated as following:

Q_{learned}=γQ_{learned,1}+(1−γ)Q_{learned,2}

where γ as the weighting average can take a pre-defined constant or a dynamic value depending on the estimation conditions under which each estimation occurred.

The overall capacity of the battery is updated as follows:

Q=α_{new}Q_{old}+(1−α_{new})Q_{learned}

where α_{new} is a function of time since last update, degradation since last update as captured by Q_{old} and Q_{learned}, and consistency value which determines the confidence level of the new learned value.

Parameter α_{new} is calculated as follows:

$${α}_{n e w} = α \frac{\sqrt{T + {T}_{1}}}{\sqrt{T + {T}_{c}}} . β$$

where α∈[0,1] is a function of consistency value ϑ, T is the life of the battery, T₁ is the pre-defined calibrated time, and T_{c} is the time passed since the last estimation, and parameter β∈[0,1] is a function of Q_{learned}/Q_{old}, where as Q_{learned}/Q_{old} decreases, β decreases to give more weight to new learned value. This is determined based on the fact that battery capacity normally decreases with additional usage.

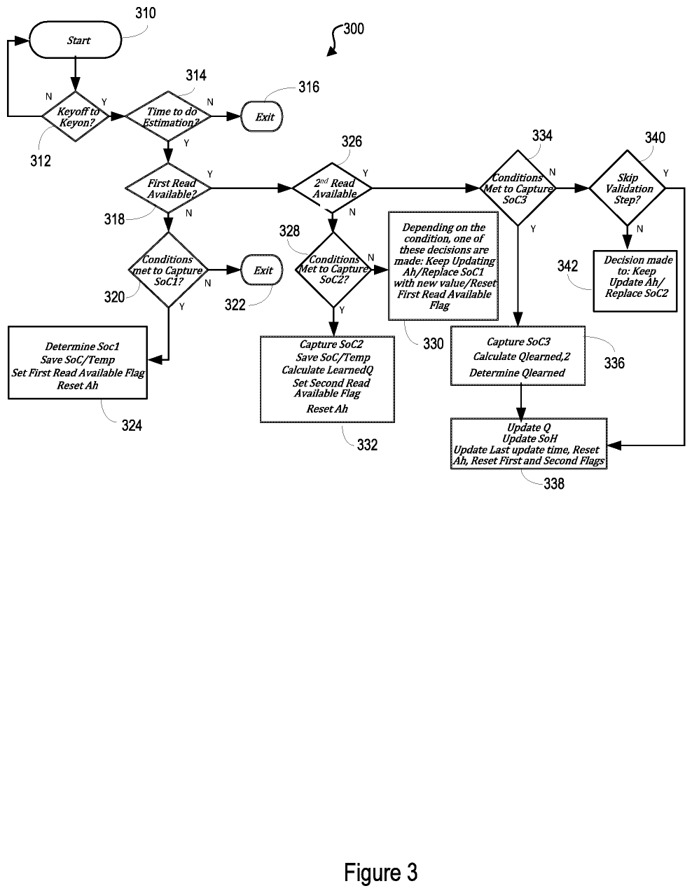

FIG. 3 is a flowchart illustrating a method for capacity estimation. The method 300 starts in block 310. In block 312 the controller determines if a Keyoff to Keyon event occurs (which may be simply referred to as a Keyon event—e.g. where the vehicle is turned from the off state to the on state). If a Keyoff to Keyon event does not occur then the method loops to block 310 and resumes waiting for the Keyoff to Keyon event. If a Keyoff to Keyon event occurs the controller determines if there is enough battery rest time to do a capacity estimation in block 314. If there is not enough battery rest time to do an estimation, then the method proceeds to block 316 and concludes (or may be restarted). If the controller determines that there is enough battery rest time to do an estimation, then the process continues to block 318. In block 318, the controller may determine if a first read of SOC is available. If a first read is not available, then the process continues to block 320. In block 320, the controller may determine if the conditions are met to capture SoC1. The conditions to capture SoC1 may include (1) sufficient battery rest time, (2) good accurate available SOC estimation, (3) battery temperature in an accepted range, (4) operation mode of the battery, and (5) other appropriate conditions as may apply. If the conditions to capture SoC1 are not met, then the method proceeds to block 322 and concludes (or may be restarted). If the conditions to capture SoC1 are met, then the method proceeds to block 324. In block 324, the controller may (1) capture SoC1, (2) save SoC1 temperature, (3) set a first read available flag to indicate a first read has been acquired, (4) reset Ah, or any combination of these elements. The method may then restart in block 310, jump to block 318, or conclude.

If the first read is available in block 318, then the method proceeds to block 326. In block 326, the controller determines if a subsequent (e.g. 2^{nd}) read of SoC is available. If a subsequent read of SoC is not available, then the method may proceed to block 328. In block 328, the controller may determine if the conditions are met to capture SoC2. The conditions to capture SoC2 may include 1) battery rest time, 2) accurate SOC estimation, 3) battery temperature, 4) battery operation mode, etc. If the conditions to capture SoC2 are not met, then the method proceeds to block 330. In block 330, the controller may 1) keep updating Ah, 2) replace SoC1 with a new value, 3) reset the first read available flag, or any combination of these elements. If the conditions to capture SoC2 are met, then the method proceeds to block 332. In block 332, the controller may 1) capture SoC2, 2) save SoC2 temperature, 3) calculate Q_{learned,1}, 4) set a second read available flag to indicate a second read has been acquired, 5) reset Ah, or any combination of these elements. The method may then restart in block 310, jump to block 326, or conclude.

If the subsequent (e.g. 2^{nd}) read is available in block 326, the method may proceed to block 334. In block 334, the controller determines if conditions are met to capture SoC3. The conditions to capture SoC3 may include 1) battery rest time, 2) time passed since last SoC read, 3) accurate SoC estimation, 4) battery temperature, 5) battery operation mode, etc. The conditions to acquire SoC3 could generally be more relaxed to facilitate the validation of capacity learning procedure and its update. If the conditions to capture SoC3 are met, then the method proceeds to block 336. In block 336, the controller may 1) capture SoC3, 2) calculate Q_{learned,2}, 3) determine Q_{learned}, or any combination of these elements. The method may then proceed to block 338. In block 338, the controller may update Q, update SoH, update last update time, reset Ah, reset first and second reading available flags, or any combination of these elements. The method may then conclude or restart in block 310.

If the conditions are not met to capture SoC3, the method may proceed to block 340. In block 340, the controller determines if the validation step should be skipped. If the controller determines that the validation step should not be skipped, the method proceeds to block 342. In block 342, the controller decides whether to keep Ah, update Ah, replace SoC2, or any combination of these elements. If the controller determines that the validation step should be skipped, the method proceeds to block 338. In block 338, the controller may 1) update Q, 2) update SoH, 3) update last update time, 4) reset Ah, 5) reset first and second reading available flags, or any combination of these elements. The method may then conclude or restart in block 310.

The proposed method improves the capacity estimation on a few fronts, including estimation accuracy, validation of learned capacity, facilitation of capacity estimation and accommodation of different battery operating and storage conditions.

A validation step is added to the method to validate the learned value of battery capacity Q. This will improve the accuracy of estimated capacity and state of health. It also provides a framework to verify the estimated value and make corrective action if required where current state of art uses an open-loop estimation in which a one-time bad estimated value of capacity will forever affect capacity estimation and leaves no choice to perform any correction.

A validation step not only improves the accuracy on the new learned value but also provides a framework that can validate the old learned value of capacity based on the consistency level acquired between the two new learned values of capacity.

The capacity estimation mechanism is also enhanced to better accommodate different driving patterns. As a result, capacity estimation is facilitated which allows to perform estimation more regularly and avoid delays in estimation due to some driving conditions which impose limitations on accumulated Ah, or ΔSoC, or battery rest time.

Also, the update scheme of the capacity is modified in order to consider the accuracy achieved in validation, and also the contribution of Q_{old} and Q_{learned} in the estimation of new value is adjusted dynamically based on battery aging happened since last update of capacity.

The methods, devices, units, controllers, modules, units, engines, and logic described above may be implemented in many different ways and in many different combinations of hardware and software. For example, all or parts of the implementations may be circuitry that includes an instruction processor, such as a Central Processing Unit (CPU), microcontroller, or a microprocessor; an Application Specific Integrated Circuit (ASIC), Programmable Logic Device (PLD), or Field Programmable Gate Array (FPGA); or circuitry that includes discrete logic or other circuit components, including analog circuit components, digital circuit components or both; or any combination thereof. The circuitry may include discrete interconnected hardware components and/or may be combined on a single integrated circuit die, distributed among multiple integrated circuit dies, or implemented in a Multiple Chip Module (MCM) of multiple integrated circuit dies in a common package, as examples.

The circuitry may further include or access instructions for execution by the circuitry. The instructions may be stored in a tangible storage medium that is other than a transitory signal, such as a flash memory, a Random Access Memory (RAM), a Read Only Memory (ROM), an Erasable Programmable Read Only Memory (EPROM); or on a magnetic or optical disc, such as a Compact Disc Read Only Memory (CDROM), Hard Disk Drive (HDD), or other magnetic or optical disk; or in or on another machine-readable medium. A product, such as a computer program product, may include a storage medium and instructions stored in or on the medium, and the instructions when executed by the circuitry in a device may cause the device to implement any of the processing described above or illustrated in the drawings.

The implementations may be distributed as circuitry among multiple system components, such as among multiple processors and memories, optionally including multiple distributed processing systems. Parameters, databases, and other data structures may be separately stored and managed, may be incorporated into a single memory or database, may be logically and physically organized in many different ways, and may be implemented in many different ways, including as data structures such as linked lists, hash tables, arrays, records, objects, or implicit storage mechanisms. Programs may be parts (e.g., subroutines) of a single program, separate programs, distributed across several memories and processors, or implemented in many different ways, such as in a library, such as a shared library (e.g., a Dynamic Link Library (DLL)). The DLL, for example, may store instructions that perform any of the processing described above or illustrated in the drawings, when executed by the circuitry.

As a person skilled in the art will readily appreciate, the above description is meant as an illustration of implementation of the principles this disclosure. This description is not intended to limit the scope or application of this system in that the system is susceptible to modification, variation and change, without departing from the spirit of this disclosure, as defined in the following claims.

1. A battery management system for an electric vehicle, the battery management system comprising:
a battery cell or pack;
a battery controller connected to the battery pack, the battery controller being configured to acquire a first reading of battery terminal voltage, battery temperature, or battery current throughput of the battery cell or pack in response to first criteria being met, acquire a second reading of battery terminal voltage, battery temperature, or battery current throughput of the battery cell or pack in response to second criteria being met, and determine an estimated capacity of the battery cell or pack, the battery controller being further configured to validate the estimated capacity in response to third criteria are met.

2. The system of claim 1, wherein battery controller is configured to determine the estimated capacity based on state of charge of battery at two different time instants and an accumulated ampere-hour between the time instants.

3. The system of claim 1, wherein the estimated capacity of each battery cell is determined periodically.

4. The system of claim 1, where the estimated capacity of each battery cell involves two different learned values of capacity and one old value of capacity.

5. The system of claim 1, wherein state of charge values are acquired based on OCV of the battery cell or pack in equilibrium state.

6. The system of claim 1, wherein the battery controller is configured to determine if the battery capacity needs to be updated based on the time passed since last update of capacity.

7. The system of claim 1, wherein the battery controller is configured to determine the temperature of the battery at the time of the SoC read.

8. The system of claim 1, wherein the battery controller is configured to determine if the battery has reached an equilibrium state.

9. The system of claim 1, wherein the battery controller is configured to determine based on temperature and battery rest time, to read a first value of SoC if a capacity update has to be performed.

10. The system of claim 9, wherein the battery controller is configured to determine to read a second value of SoC.

11. The system of claim 10, wherein the battery controller is configured to determine the difference ΔSoC between the second value of SoC, and the first value of SoC, and determine the battery rest time.

12. The system of claim 11, wherein the battery controller is configured to further analyze ΔSoC and battery rest time, and determine a capacity learning procedure shall be initiated, or reset the procedure, or wait and record Ah, or replace the first value of SoC with the second value of SoC and record Ah.

13. The system of claim 10, wherein the battery controller is configured to determine the learned capacity using ΔSoC and Ah recorded capacity between first and second value of SoC.

14. The system of claim 1, wherein the battery controller is configured to determine whether a validation of learned capacity is required.

15. The system of claim 10, wherein the battery controller is configured to determine based on temperature and battery rest time, to read a third value of SoC.

16. The system of claim 15, wherein the battery controller is configured to determine the difference ΔSoC between the third value of SoC, and the second value of SoC, and calculates the battery rest time.

17. The system of claim 16, wherein the battery controller is configured to further analyze ΔSoC and battery rest time, and determines a capacity learning procedure shall be initiated, or reset the procedure, or wait and record Ah, or replace the second value of SoC with the third value of SoC and record Ah.

18. The system of claim 17, wherein the battery controller is configured to determine a second learned capacity using ΔSoC and Ah recorded capacity between the second value of SoC and the third value of SoC.

19. The system of claim 18, wherein the battery controller is configured to determine a validation index with respect to nominal capacity of battery based on the first learned capacity and second learned capacity.

20. The system of claim 19, wherein the battery controller is configured to determine based on the validation index to update capacity or discard new learning values.

21. The system of claim 20, wherein the battery controller is configured to further analyze the validation index to determine an impact of new learned values in an overall capacity update.

22. The system of claim 19, wherein the battery controller is configured to perform an adaptive averaging between the first and second learned capacity values to identify a new learned capacity of battery.

23. The system of claim 22, wherein the battery controller is configured to compare the new learned capacity with the last valid capacity of the battery, analyzes a time passed since a last valid value to identify a depth of aging the battery cell or pack has gone through.

24. The system of claim 23, wherein the battery controller is configured to employ an analysis of the depth of aging to tune an averaging algorithm with the new learned value of capacity and an old valid value.

25. The system of claim 24, wherein the battery controller is configured to update the estimated capacity based on the new learned value, the old valid value, and a tuning mechanism.
